(19) United States
(12) Patent Application Publication
(10) Pub. No.: US 2014/0078687 A1
(43) Pub. Date: Mar. 20, 2014

(54) DEVICE MOUNTING BOARD, SEMICONDUCTOR MODULE, AND METHOD FOR FABRICATING THE DEVICE MOUNTING BOARD

(71) Applicant: SANYO ELECTRIC CO., LTD., Osaka (JP)

(72) Inventors: Yasuhiro KOHARA, Osaka (JP); Masayuki NAGAMATSU, Gifu (JP); Koutaro DEGUCHI, Osaka (JP)

(73) Assignee: SANYO ELECTRIC CO., LTD., Osaka (JP)

(21) Appl. No.: 14/089,523

(22) Filed: Nov. 25, 2013

Related U.S. Application Data
(63) Continuation of application No. PCT/JP2012/006032, filed on Sep. 21, 2012.

(30) Foreign Application Priority Data
Sep. 28, 2011 (JP) 2011-213284

(51) Int. Cl. H05K 1/02; H05K 3/00

(52) U.S. Cl. CPC H05K 1/021; H05K 3/00
USPC 361/746; 174/255; 361/767; 427/97.3

(57) ABSTRACT

A device mounting board includes a metallic substrate, an oxide film formed such that the surfaces of the metallic form are oxidized, an insulating resin layer disposed on the oxide film facing one main surface of the metallic layer, and a wiring layer disposed on the insulating resin layer. The film thickness of a certain partial region of the oxide film disposed below a first semiconductor device is greater than that of the other regions surrounding the partial region of the oxide film. Conversely, the film thickness of the insulating resin layer underneath a second semiconductor device is less than that of the insulating resin layer underneath the first semiconductor device.

### BACKGROUND OF THE INVENTION

1. Field of the Invention

The present disclosure relates to a device mounting board, a semiconductor module, and a method for fabricating the device mounting board.

2. Description of the Related Art

Although the use of ceramic material that excels in characteristics of thermal conductivity as an insulating layer is suitable for the purpose of spreading the heat generated by a power semiconductor device, a ceramic substrate is very expensive. In contrast, a control semiconductor device generates less heat than the power semiconductor device does. Thus, mounting the power semiconductor device and the control semiconductor device on the expensive ceramic substrate may be more than necessary. Besides, if the power semiconductor device and the control semiconductor device are mixed on the ceramic substrate with high thermal conductivity, the heat generated by the power semiconductor device will be transmitted to the control semiconductor device. This in turn heats the control semiconductor to a high temperature, causing a problem where the control semiconductor device becomes out of control (heat runaway). In order to resolve such a problem, the use of an insulating resin layer in which the insulating resin is filled with a ceramic filler is disclosed in Reference (1) in the following Related Art List.

### RELATED ART LIST

(1) Japanese Patent Application Publication No. 2003-303940.
(2) Japanese Patent Application Publication No. Hei05-191001.
(3) Japanese Patent Application Publication No. 2008-159647.

As cited in Reference (1), it is difficult to achieve a technology where both high thermal conductivity and high dielectric breakdown characteristic can be attained by use of the insulating layer filled with the filler.

### SUMMARY OF THE INVENTION

The present disclosure has been made in view of the foregoing circumstances, and one non-limiting and exemplary embodiment provides a technology capable of satisfying a characteristic of thermal conductivity and a dielectric breakdown characteristic required of a power semiconductor device mounting part and capable also of suppressing the transmission of the heat generated by a power semiconductor device to a control semiconductor device, in a device mounting board where the power semiconductor device generating much heat and the control semiconductor device low in the heat generation are mixed together. Here, a power transistor, such as a power MOSFET (Metal-Oxide-Semiconductor Field-Effect Transistor) and IGBT (Insulated Gate Bipolar Transistor), or an LED device or the like may be used for the power semiconductor device, whereas a gate drive IC, an illuminance sensor, or the like may be used for the power semiconductor device.

One embodiment of the present invention relates to a device mounting board. The device mounting board includes: a metallic substrate; an oxide film formed such that surfaces of the metallic substrate are oxidized; an insulating resin layer provided on the oxide film that faces one main surface of the metallic substrate; and a wiring layer provided on the insulating resin layer, wherein the thickness of at least part of the oxide film is greater than that of the other parts of the oxide film.

Another embodiment of the present invention relates to a semiconductor module. The semiconductor module includes: the above-described device mounting board; and a semiconductor device electrically connected to the wiring layer, the semiconductor device being mounted on a main surface of the device mounting board on a side where the wiring layer is formed.

Still another embodiment of the present invention relates to a method for fabricating a device mounting board. The method for fabricating a device mounting board includes: forming a protruding portion on a predetermined region of a metallic substrate; roughing a surface of the protruding portion formed on the metallic substrate; forming an oxide film on a surface of the metallic substrate by performing an oxidation treatment; forming an insulating resin layer on the oxide film; and forming a wiring layer in a manner such that a metal layer is formed on the insulating resin layer and then the metal layer is selectively removed.

Additional benefits and advantages of the disclosed embodiments will be apparent from the specification and Figures. The benefits and/or advantages may be individually provided by the various embodiments and features of the specification and drawings, and need not all be provided in order to obtain one or more of the same.

These general and specific aspects may be implemented using a system, a method, and a computer program, and any combination of systems, methods, and computer programs.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a cross-sectional view showing a rough structure of a semiconductor module including a device mounting board according to a first embodiment;

FIGS. 2A to 2D are cross-sectional views to explain an outline of processes in a method for fabricating a device mounting board and a semiconductor module according to a first embodiment;

FIGS. 3A to 3C are cross-sectional views to explain an outline of processes in a method for fabricating a device mounting board and a semiconductor module according to a first embodiment;

FIGS. 4A and 4B are cross-sectional views to explain an outline of processes in a method for fabricating a device mounting board and a semiconductor module according to a first embodiment;

FIG. 5 is a cross-sectional view showing a rough structure of a semiconductor module including a device mounting board according to a second embodiment;

FIGS. 6A to 6C are cross-sectional views to explain an outline of processes in a method for fabricating a device mounting board and a semiconductor module according to a second embodiment; and

FIG. 7 is a cross-sectional view showing a rough structure of a semiconductor module including a device mounting board according to a third embodiment.

### DETAILED DESCRIPTION

The present disclosure will now be described by reference to the exemplary embodiments. This does not intend to limit the scope of the present disclosure, but to exemplify the disclosure.

Hereinafter, the exemplary embodiments of the present disclosure or the present invention, will be described based on the accompanying drawings. The same or equivalent constituents, members, or processes illustrated in each drawing will be denoted with the same reference numerals, and the repeated descriptions thereof will be omitted as appropriate. The exemplary embodiments do not intend to limit the scope of the invention but exemplify the invention. All of the features and the combinations thereof described in the embodiments are not necessarily essential to the invention.

### First Embodiment

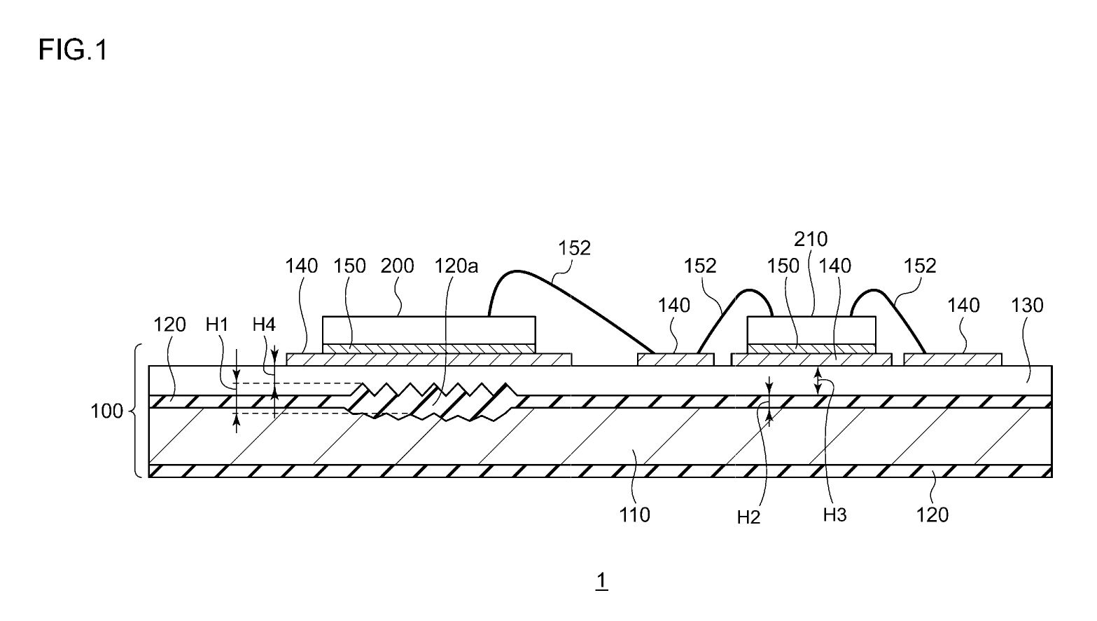

FIG. 1 is a cross-sectional view showing a rough structure of a semiconductor module including a device mounting board according to a first embodiment. A semiconductor module 1 according to the first embodiment includes a device mounting board 100 and semiconductor devices 200 and 210 mounted on one main surface of the device mounting board 100. The semiconductor device 200 is a power semiconductor device such as a transistor, an IGBT (Insulated Gate Bipolar Transistor), or a MOSFET (Metal-Oxide-Semiconductor Field-Effect Transistor). The semiconductor device 210 is a control semiconductor device such as a control IC or the like.

The device mounting board 100 is comprised of a metallic substrate 110, oxide films 120, an insulating resin layer 130, and a wiring layer 140.

The metallic substrate 110 may be a substrate formed of a metal, which displays good thermal conductivity, such as aluminum or an aluminum alloy. In the first embodiment, the metallic substrate 110 is an aluminum substrate. The thickness of the metallic substrate 110 may be 0.5 mm to 2 mm, for instance.

The oxide film 120 is an insulating film formed such that the surfaces of the metallic substrate 110 are oxidized. In the present embodiment, the oxide film 120 is formed of aluminum oxide (alumina). The oxide films 120 coat the top surface and the underside of the metallic substrate 110. Where the main surface of the device mounting board 100 is viewed planarly, the thickness H1 of a partial region of the oxide film 120 overlapped with the semiconductor device 200 is larger than the thickness H2 of regions surrounding said partial region thereof. More specifically, the thickness H1 of the oxide film 120, which coasts the main surface of the metallic substrate 110 on a side which the wiring layers 140 are provided, underneath the semiconductor device 200 is larger than the thickness H2 of regions surrounding said partial region thereof. Hereinafter, said partial region thereof that coats a top surface of the metallic substrate 110 will be referred to as an oxide film 120a and therefore this oxide film 120a will be distinguished from the other parts of the oxide film 120. Although, in the present embodiment, the oxide film 120a is formed across the entire region corresponding to the overlapped portion thereof with the semiconductor device 200, the oxide film 120a may instead be formed partially on the overlapped portion thereof with the semiconductor device 200. Also, the oxide film 120a may contain a part of regions that are not overlapped with the semiconductor device 200.

The thickness H1 of the oxide film may be, for example, 1.02 to 2 times the thickness H2 of the oxide film 120 excluding the oxide film 120a.

The insulating resin layer 130 is provided on the oxide film 120 that faces one main surface of the metallic substrate 110. The insulating resin layer 130 is laminated on the top surface of the oxide film 120. The material used to form the insulating resin layer 130 may be, for instance, a melamine derivative, such as BT resin, or a thermosetting resin, such as liquid-crystal polymer, epoxy resin, PPE resin, polyimide resin, fluorine resin, phenol resin or polyamide bismaleimide. From the viewpoint of improving the of the device mounting board 100, it is suitable that the insulating resin layer 130 has a high thermal conductivity. In this respect, the insulating resin layer 130 contains, as a high thermal conductive filler, alumina, aluminum nitride, silica, or the like, for instance. Thereby, the heat generated by the power semiconductor device 200 in particular can be released efficiently.

The thickness of the insulating resin layer 130 may be 50 μm to 250 μm, for instance. As described earlier, the film thickness H3 of the insulating resin layer 130 disposed underneath the semiconductor device 210 is smaller than the film thickness H4 of the insulating resin layer 130 disposed underneath the semiconductor device 200 by the increased thickness of the oxide film 120a over that of the surrounding regions of the oxide film 120.

The wiring layer 140 is provided on top of the insulating resin layer 130. The wiring layer 140, which is formed of copper, for instance, has a predetermined wiring pattern. The thickness of the wiring layer 140 may be 10 μm to 150 μm, for instance.

The semiconductor devices 200 and 210 are mounted on the main surface of the device mounting board 100 on a side thereof where the wiring layer 140 is formed. Device electrodes (not shown) at lower surface sides of the semiconductor devices 200 and 210 are electrically connected to the wiring layers 140 (electrodes) by way of solders 150. A metal paste or adhesive may be used instead of the solder. Device electrodes (not shown) at upper surface sides of the semiconductor devices 200 and 210 are wire-bonded to the wiring layers 140 using aluminum wires 152, for instance. Copper wires or gold wires may be used instead of the aluminum wires. In the present embodiment, an aluminum wire 152 connected to one of the device electrodes at the upper surface of the semiconductor device 210 and another aluminum wire 152 connected to one of the device electrodes at the upper surface of the semiconductor device 200 are both connected to a part of the wiring layer 140. For example, a control signal with which to control the operation of the semiconductor device 200 is transmitted from the semiconductor device 210 to the semiconductor device 200, and the semiconductor device 200 performs a switching operation according to the control signal.

(A Method for Fabricating a Device Mounting Board and a Semiconductor Module)

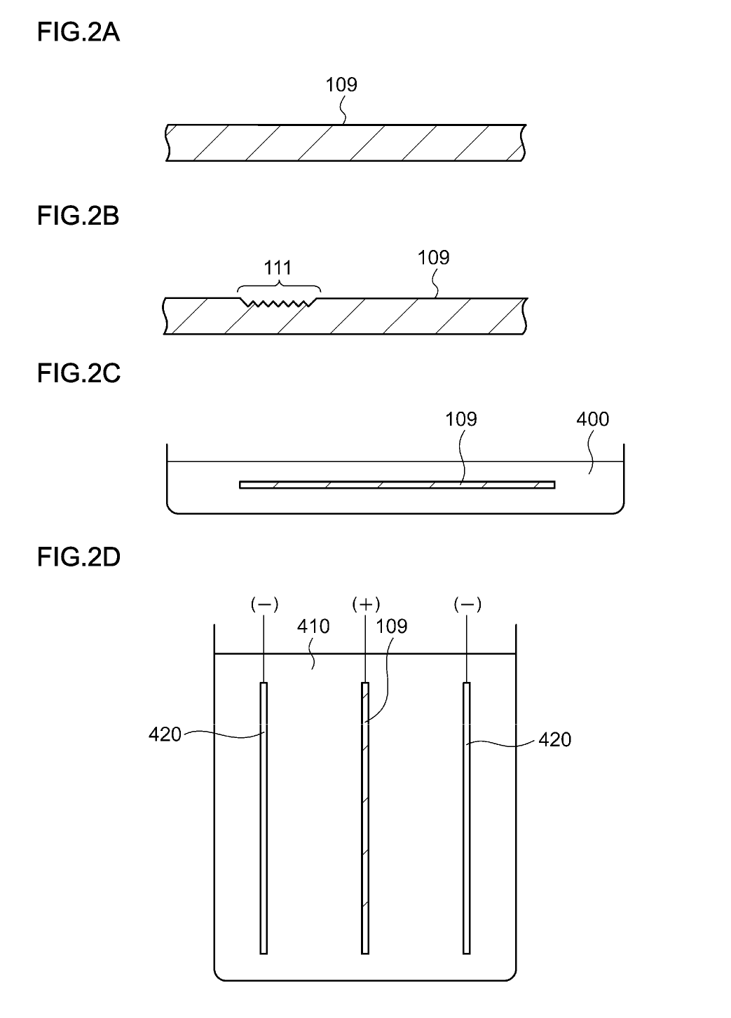

A manufacturing process for a semiconductor module including a device mounting board according to the first embodiment will now be described with reference to FIGS. 2A to 2D, FIGS. 3A to 3C, and FIGS. 4A and 4B.

As illustrated in FIG. 2A, a metallic sheet 109 formed mainly of aluminum is first prepared. The metallic sheet 109 is a large-sized plate before being subjected to a punching process where it is separated into individual metallic substrates 110. Here, the metallic sheet 109 is of an approximately square shape with the side length of 100 mm to 1000 mm, for instance. Then, as illustrated in FIG. 2B, a plurality of protruding portions 111 are formed in a predetermined mounting region of the semiconductor device 200. The height of the protruding portions 111 is 0.1 to 0.2 mm, for instance. A method employed for the formation of the protruding portions 111 is not limited to any particular one and may be a die and mold machining by means of press, for instance.

Then, as illustrated in FIG. 2C, the metallic sheet 109 is immersed in a sulphuric acid solution 400, and the surfaces of the metallic sheet 109 are subjected to an etching such as slight etching. During a process in which a surface of the metallic sheet 109 is processed to have asperities, a conspicuous processing strain occurs in the protruding portions 111 formed in the metallic sheet 109, thereby damaging the crystals. As a result, a large number of fine crystal grains are formed in the protruding portion 111 as compared with other regions of the metallic sheet 109. Thus, performing the etching on the surface of the metallic sheet 109 forms a finer roughness or finer asperities in the protruding portions 111 than in other regions of the surface of the metallic sheet 109.

Then, an oxide film 120 is formed on the surfaces of the metallic sheet 109 by performing an oxidation treatment. In the first embodiment, as shown FIG. 2D, the metallic sheet 109, which is connected to a positive electrode of a not-shown power supply, is immersed in an oxalate solution 410, for instance. Also, cathode terminals 420, which are each connected to a negative electrode of the power supply, are disposed counter to each other at predetermined intervals from both main surfaces of the metallic sheet 109 (i.e., the metallic sheet 109 are interposed between the cathode terminals 420 spaced apart from the metallic sheet 109 at the predetermined intervals, respectively). Then, the metallic sheet 109 undergoes anodic oxidation and, thereby, oxide films formed of aluminum oxide are formed on the surfaces of the metallic sheet 109. The oxidation treatment of the metallic sheet 109 may be achieved by the use of a plasma oxidation. In this plasma oxidation, an alternate current is applied between the metallic sheet 109, which serves as the positive electrode, and the negative electrodes in a neutral or alkaline treatment liquid, and a plasma discharge (micro arc) is generated so as to oxidize the surfaces of the metallic sheet 109.

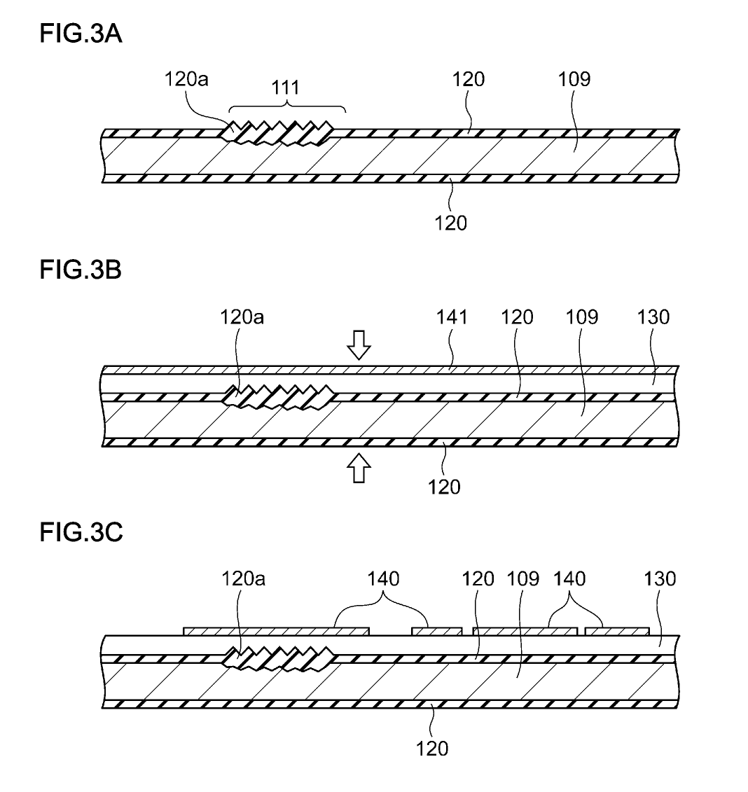

The oxidation treatment of the metallic sheet 109 forms a surface layer 120, of the metallic sheet 109, which is the oxide film 120. As a result, as illustrated in FIG. 3A, the surface of the metallic sheet 109 is coated with the oxide film 120. As described above, the metallic sheet 109 is formed such that finer asperities are formed on the surface of the protruding portions 111 as compared with other regions of the surface of the metallic sheet 109. Thus, the protruding portions 111 are more likely to be oxidized than other regions of the surface thereof. Hence, the oxide film 120a, whose film thickness is larger than that of other regions of surface thereof, is formed in the protruding portions 111.

Then, as illustrated in FIG. 3B, an insulating resin layer 130 formed of an insulating resin film is placed on top of the oxide film 120 provided at an upper surface side of the metallic sheet 109. Also, a metallic foil 141 such as copper foil is placed on top of the insulating resin layer 130. Then, the metallic substrate 110, the insulating resin layer 130 and the metallic foil 141 are press-bonded together using a press machine.

Then, as illustrated in FIG. 3C, the metallic foil 141 is selectively removed so as to form wiring layers 140 of a predetermined pattern by using known photolithography method and etching method.

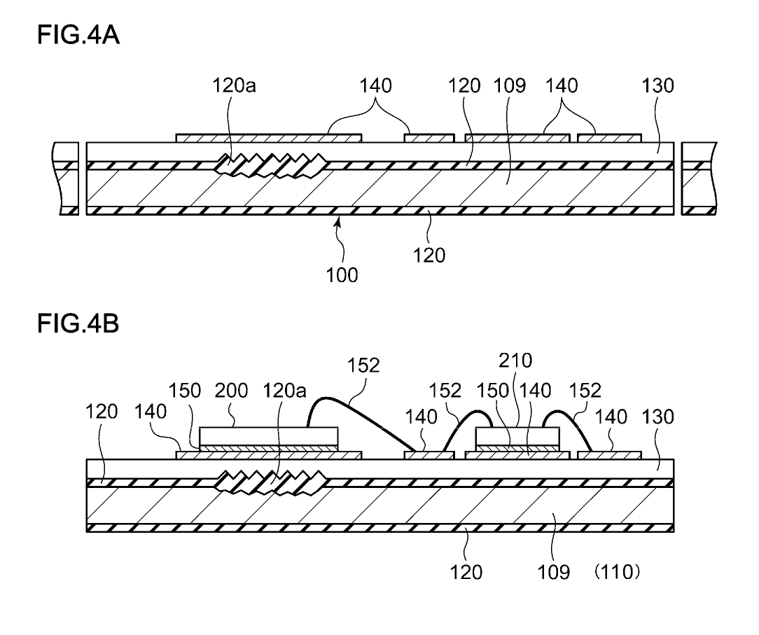

Then, as illustrated in FIG. 4A, the punching process or cutting process is performed so as to have separated individual device mounting boards 100. Through the processes as described above, the device mounting board 100 according to the first embodiment is formed.

Then, as illustrated in FIG. 4B, semiconductor devices 200 and 210 are mounted on the wiring layers 140 by way of solders 150. The device electrodes at upper surface sides of the semiconductor devices 200 and 210 are electrically connected to predetermined regions of the wiring layers 140 by way of aluminum wires 152 by using a wire bonding method. Through the processes as described above, the semiconductor module 1 according to the first embodiment is formed.

As described earlier, the thickness of the oxide film 120 is locally made thicker, so that a partial region, whose thermal conductivity and dielectric breakdown voltage are higher than that of regions surrounding said partial region. By mounting the semiconductor device 200, which is the heat generation source, above this partial region, both high thermal conductivity and high dielectric breakdown characteristic underneath the semiconductor device 200 can be attained. At the same time, the thickness of the insulating resin layer 130 underneath the semiconductor device 210, which is relatively low in heat generation, is larger than the thickness of the insulating resin layer 130 underneath the semiconductor device 200. This structure suppresses the transfer of heat generated by the semiconductor device 200 to the metallic substrate 110 and the transfer of the thus generated heat to the semiconductor device 210 via the metallic substrate 110. Thus, it is less likely to increase the temperature of the semiconductor device 210 via the metallic substrate 110 in the even that the semiconductor device 200 generates heat. As a result, the operation reliability of the semiconductor device 210 can be improved.

Also, the semiconductor module 1 according to the first embodiment is configured such that the semiconductor device 200 (power semiconductor device) and the semiconductor device 210 (control semiconductor device) are mounted on the above-described device mounting board 100. Thus, both high dielectric breakdown characteristic and high thermal conductivity in the power semiconductor device are ensured without causing an increase in temperature of the control semiconductor device. Hence, the operation reliability of the semiconductor module 1 can be improved.

### Second Embodiment

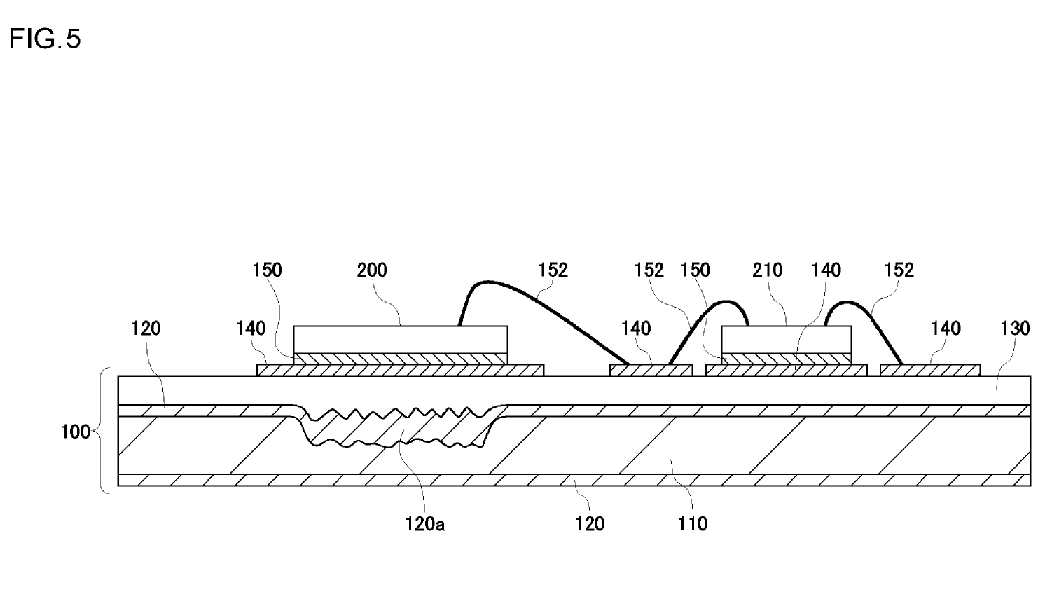

FIG. 5 is a cross-sectional view showing a rough structure of a semiconductor module including a device mounting board according to a second embodiment. A feature of the second embodiment different from the features of the above-described first embodiment is described hereunder. That is, the second embodiment is characterized in that the surface of a partial region of the oxide film 120, whose film thickness is larger than that of other regions thereof, is disposed at the same height (level) of the surfaces of other regions thereof or the partial surface thereof is formed further toward the metallic substrate 110, namely more inwardly toward the metallic substrate 110, than the surfaces of the other regions thereof.

(A Method for Fabricating a Device Mounting Board and a Semiconductor Module)

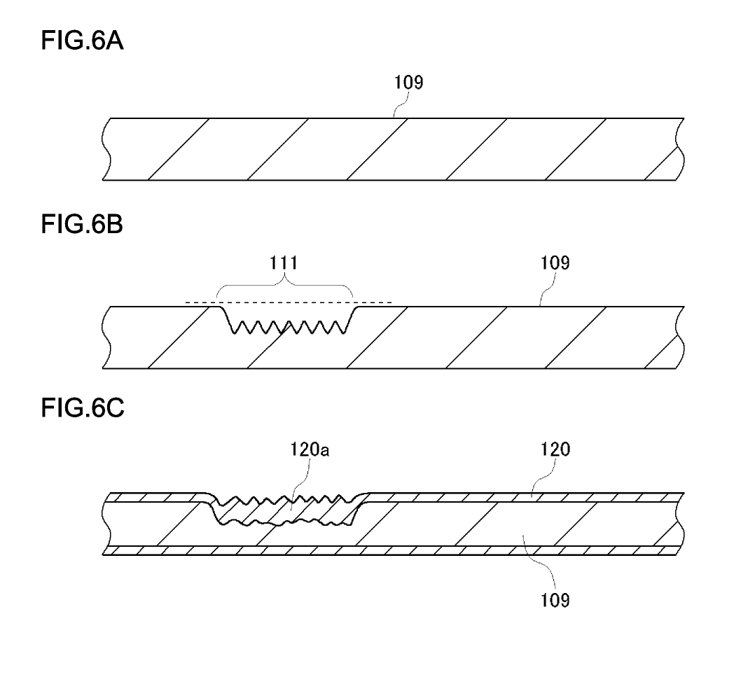

A manufacturing process for a semiconductor module including a device mounting board according to the second embodiment will now be described with reference to FIGS. 6A to 6C.

As illustrated in FIG. 6A, a metallic sheet 109 formed mainly of aluminum is first prepared. The metallic sheet 109 is a large-sized plate before being subjected to the punching process where it is separated into individual metallic substrates 110. Here, the metallic sheet 109 is of an approximately square shape with the side length of 100 mm to 1000 mm, for instance.

Then, as illustrated in FIG. 6B, a plurality of protruding portions 111 are formed in a predetermined mounting region of the semiconductor 200. The height of the protruding portions 111 is 0.1 to 0.2 mm, for instance. In this process shown in FIG. 6B, the tips of the protruding portions 111 are positioned such that the tips thereof are formed further inwardly into and toward the metallic sheet 109 relative to the surfaces of the metallic sheet 109 where no protruding portions 111 is formed. A method employed for the formation of the protruding portions 111 is not limited to any particular one and may be a die and mold machining by means of press, for instance.

After this process of FIG. 6B, the oxide film 120 is formed on a surface layer of the metallic sheet 109, as shown in FIG. 6, by employing a method similar to that used in the first embodiment.

Used in the second embodiment is the metallic sheet 109 where the tips of the protruding portions 111 are positioned further inwardly into and toward the metallic sheet 109 relative to the surfaces of the metallic sheet 109 where no protruding portions 111 is formed. Thus, the metallic sheet 109 as shown in FIG. 6C can be formed where the surface of the oxide film 120a, whose film thickness is larger than that of other regions thereof, is positioned at the same height (level) of the surfaces of other regions thereof or the partial surface thereof is positioned further toward the metallic sheet 109 than the surfaces of the other regions thereof. The metallic sheet 109 becomes the metallic substrate 110 as shown in FIG. 5 through a dicing step, of cutting the board into a plurality of separated individual elements, such as the punching process.

As described above, the protruding portion s 111 are provided in the metallic substrate 110 such that the tips of the protruding portions 111 are positioned further inwardly into and toward the metallic substrate 110 relative to the surfaces of the metallic substrate 110 where no protruding portions 111 is formed and such that the thickness of the oxide film 120 is locally made thicker. As a result, the metallic substrate 110 can be formed where the surface of the oxide film 120a, which is thicker than other regions thereof, is disposed at the same height of the surfaces of other regions thereof or the partial surface thereof is positioned further toward the metallic substrate 110 than the surfaces of the other regions thereof.

Since the surface of the region of the oxide film 120a is positioned at the same height of the surfaces of other regions thereof or is positioned further toward the metallic substrate 110 than the surfaces of the other regions thereof, the dielectric breakdown voltage of the oxide film 120a can be raised relative to the other regions thereof by the increased thickness of the oxide film 120a over that of the other regions of the oxide film 120. Also, when the surface of the insulating resin layer 130 facing the wiring layer 140 is formed flat, the film thickness of the insulating resin layer 130 on the oxide film 120 can be made thicker in the oxide film 120a, so that the dielectric breakdown voltage of the insulating resin layer 130 can be raised. In this manner, the dielectric breakdown strength of the device mounting board 100 can be improved and the dielectric breakdown can be suppressed and therefore the reliability can be improved.

### Third Embodiment

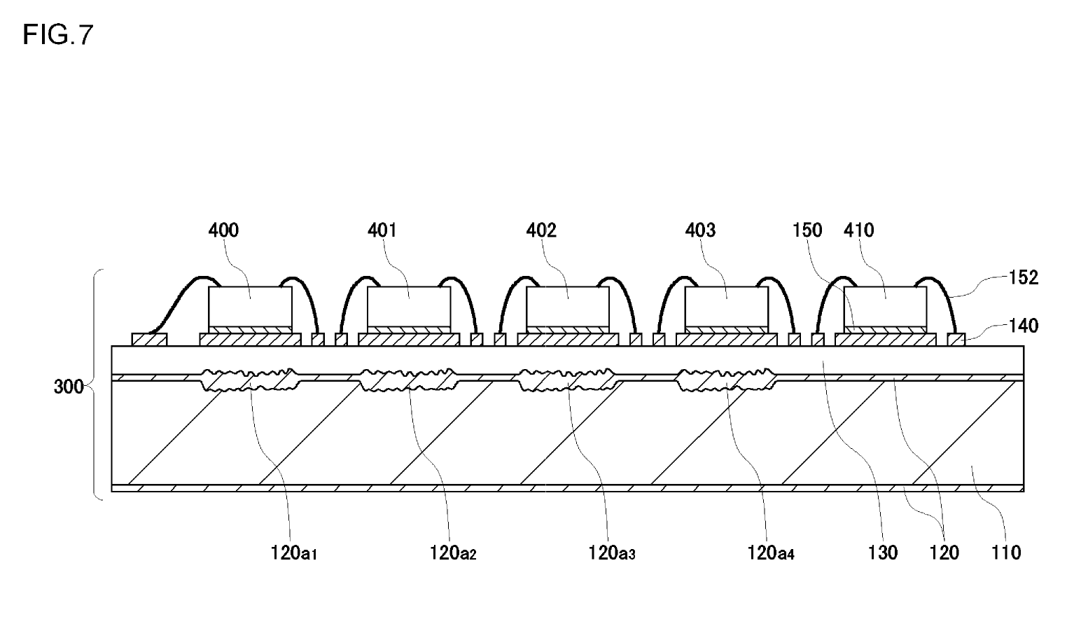

FIG. 7 is a cross-sectional view showing a rough structure of a semiconductor module including a device mounting board according to a third embodiment. In FIG. 7, a semiconductor device 400 is a blue LED device, a semiconductor device 401 is a green LED device, a semiconductor device 402 is a red LED device, and a semiconductor device 403 is a white LED device. A semiconductor device 410 is an illuminance sensor used to control the LED devices, and a semiconductor module 300 is an LED module. The LED devices 400 to 403 are mounted respectively on regions 120a1 to 120a4, of an oxide film 120, whose film thickness is larger than the film thickness of the surrounding regions thereof. Here, the thicker regions 120a1 to 120a4 are isolated for each of the respective LED devices 400 to 403. Since in this structure the heats generated by the respective LED devices 400 to 403 are isolated for each one of them, the heat generated by one LED is less likely to be transmitted to its adjacent LED or LEDs and therefore the effect of the heat generated by adjacent LEDs on the operation characteristics of LEDs can be suppressed. For example, the drop in luminous intensity of the red LED, whose luminous intensity drops when the ambient temperature rises on account of the heat generated by the surrounding LEDs, can be suppressed by employing the structure according the third embodiment. Also, a thermally-weak illuminance sensor can be mounted on the same substrate as that which mounts the LED devices while the thermally-weak illuminance sensor is thermally isolated from the LED devices. Thus, the size of the LED module can be reduced.

FIG. 7 discloses an exemplary embodiment where the LED devices 400 to 403 are respectively mounted above the thicker oxide films 120a1 to 120a4, which are isolated for every one of the LED devices 400 to 403. However, this structure should not be considered as limiting and, for example, the LED devices 400 to 403 may be mounted above one thick oxide film (e.g., the oxide film 12a1), which is not isolated for each of a plurality of LED devices. According to this modification, the thick oxide film 120a1 that excels in thermal conductivity is formed in a large area as compared with the case where the oxide films 120a1 to 120a4 are isolated from each other. Thus this modification is advantageous in that the thermal conductivity for the module as a whole is enhanced. The third embodiment and its modification that excel in thermal conductivity are suitable to the case where a plurality of LEDs of the same type are mounted on the device mounting board.

The description has been given of the example where the four LED devices are mounted in FIG. 7. The combination of types of LED devices and the number of LED devices used in the LED module are not limited thereto. Also, passive components such as variable resistors may be mounted in the LED module. The third embodiment discloses the example where the thick oxide films 120a1 to 120a4 are isolated for each LED. The modification to this third embodiment also discloses the example where a plurality of LEDs are mounted on one thick oxide film. In another modification, in the LED module where the above-described blue, green, red and white LEDs are mounted, the arrangement may be such that, for example, only an oxide film corresponding to the red LED is isolated, and the remaining blue, green and white LEDs are mounted on a same thick oxide film.

The present disclosure is not limited to the above-described embodiments and modifications only, and it is understood by those skilled in the art that various further modifications such as changes in design may be made based on their knowledge and the embodiments added with such modifications are also within the scope of the present disclosure.

What is claimed is:

1. A device mounting board comprising:
a metallic substrate;
an oxide film formed such that surfaces of the metallic substrate are oxidized;
an insulating resin layer provided on the oxide film that faces one main surface of the metallic substrate; and
a wiring layer provided on the insulating resin layer,
wherein the thickness of at least part of the oxide film is greater than that of the other parts of the oxide film.

2. A device mounting board according to claim 1, wherein a plurality of semiconductor devices having different heat generation rates are mounted, and
wherein the at least part of the oxide film whose thickness is greater than that of the other parts thereof is a predetermined mounting region of semiconductor devices, whose heat generation rate is relatively large, in the plurality of semiconductor devices.

3. A device mounting board according to claim 1, wherein the insulating resin layer, which is provided above the at least part of the oxide film whose thickness is greater than that of the other parts thereof, has a portion having a thickness less than the thickness of other parts of the insulating resin layer.

4. A device mounting board according to claim 1, wherein a surface of the at least part of the oxide film, whose thickness is greater than that of the other parts thereof, is positioned at the same height or level of surfaces of the other regions thereof or is positioned further toward the metallic substrate than the surfaces of the other regions thereof.

5. A device mounting board according to claim 1, wherein asperities are formed, on the one main surface of the metallic substrate, in the at least part of the oxide film whose thickness is greater than that of the other parts thereof.

6. A semiconductor module comprising:
a device mounting board according to claim 1; and
a semiconductor device electrically connected to the wiring layer, the semiconductor device being mounted on a main surface of the device mounting board on a side where the wiring layer is formed.

7. A method for fabricating a device mounting board, the method comprising:
forming a protruding portion on a predetermined region of a metallic substrate;
forming an oxide film on a surface of the metallic substrate by performing an oxidation treatment;
forming an insulating resin layer on the oxide film; and
forming a wiring layer in a manner such that a metal layer is formed on the insulating resin layer and then the metal layer is selectively removed.

8. A method, of fabricating a device mounting board, according to claim 7, wherein the oxidation treatment is anodic oxidation.
